(19) United States
(12) Patent Application Publication
(10) Pub. No.: US 2018/0240874 A1
(43) Pub. Date: Aug. 23, 2018

(54) RESISTANCE REDUCTION UNDER TRANSISTOR SPACERS

(71) Applicant: INTEL CORPORATION, Santa Clara, CA (US)

(72) Inventors: CORY E. WEBER, Hillsboro, OR (US); SAURABH MORARKA, Hillsboro, OR (US); RITESH JHAVERI, Hillsboro, OR (US); GLENN A. GLASS, Portland, OR (US); SZUYA S. LIAO, Portland, OR (US); ANAND S. MURTHY, Portland, OR (US)

(73) Assignee: INTEL CORPORATION, Santa Clara, CA (US)

(21) Appl. No.: 15/754,150

(22) PCT Filed: Sep. 25, 2015
(86) PCT No.: PCT/US2015/052235

§ 371 Date: Feb. 21, 2018

(51) Int. Cl. H01L 29/08; H01L 21/225; H01L 21/306; H01L 29/66; H01L 29/78; H01L 29/06; H01L 29/417

(52) U.S. Cl. CPC H01L 29/0847; H01L 21/2252; H01L 21/30612; H01L 29/41791; H01L 29/785; H01L 29/0673; H01L 29/66522; H01L 29/6681

(57) ABSTRACT

Techniques are disclosed for resistance reduction under transistor spacers. In some instances, the techniques include reducing the exposure of source/drain (S/D) dopants to thermal cycles, thereby reducing the diffusion and loss of S/D dopants to surrounding materials. In some such instances, the techniques include delaying the epitaxial deposition of the doped S/D material until near the end of the transistor formation process flow, thereby avoiding the thermal cycles earlier in the process flow. For example, the techniques may include replacing the S/D regions (e.g., native fin material in the regions to be used for the transistor S/D) with sacrificial S/D material that can then be selectively etched and replaced by highly doped epitaxial S/D material later in the process flow. In some cases, the selective etch may be performed through S/D contact trenches formed in overlying insulator material over the sacrificial S/D.

### BACKGROUND

A finFET is a transistor built around a thin strip of semiconductor material (generally referred to as the fin). The transistor includes the standard field-effect transistor (FET) nodes, including a gate, a gate dielectric, a source region, and a drain region. The conductive channel of the device resides on the outer sides of the fin beneath the gate dielectric. Specifically, current runs along/within both sidewalls of the fin (sides perpendicular to the substrate surface) as well as along the top of the fin (side parallel to the substrate surface). Because the conductive channel of such configurations essentially resides along the three different outer regions of the fin, such a finFET design is sometimes referred to as a tri-gate transistor. FinFETs also include side-wall spacers, referred to generally as spacers, on either side of the gate that help determine the channel length and help with replacement gate processes. The finFET is an example of a non-planar transistor configuration. There exists a number of non-trivial issues associated with non-planar transistors.

### BRIEF DESCRIPTION OF THE DRAWINGS

FIG. 1A illustrates an example integrated circuit structure after gate processing and including sacrificial epitaxial source/drain (S/D) material, in accordance with an embodiment of the present disclosure.

FIG. 1B illustrates a cross-sectional view of the example integrated circuit structure of FIG. 1A, the cross-section being through the middle of the right fin along plane A, in accordance with an embodiment of the present disclosure.

FIG. 2 illustrates the example integrated circuit structure of FIG. 1B, after forming S/D contact trenches in an overlying insulator layer, in accordance with an embodiment of the present disclosure

FIG. 3 illustrates the example integrated circuit structure of FIG. 2, after the sacrificial S/D material has been removed to form S/D trenches, in accordance with an embodiment of the present disclosure.

FIG. 4 illustrates the example integrated circuit structure of FIG. 3, after depositing replacement S/D material in the S/D trenches, in accordance with an embodiment of the present disclosure.

FIG. 5 illustrates the example integrated circuit structure of FIG. 4, after depositing metal S/D contacts in the contact trenches, in accordance with an embodiment of the present disclosure.

FIG. 6 illustrates variations that can be made to the example integrated circuit structure of FIG. 5, in accordance with some embodiments of the present disclosure.

FIGS. 7A-B illustrate depositing additional epitaxial material in the S/D contact trenches formed in FIG. 2, in accordance with an embodiment of the present disclosure.

FIG. 8 illustrates an example computing system implemented with integrated circuit structures or devices formed using the techniques disclosed herein, in accordance with one or more embodiments of the present disclosure.

### DETAILED DESCRIPTION

Techniques are disclosed for resistance reduction under transistor spacers. Resistance increases under transistor spacers as fin width scales due to, for example, a larger fraction of source/drain (S/D) dopant diffusing from the S/D region (e.g., from an S/D fin) into the spacer, thereby reducing carrier concentration and degrading external resistance (Rext). The dopant diffusion also makes the S/D junctions more gradual, and reduces the dopant concentration at metal/semiconductor interfaces, causing additional S/D and contact resistance degradation. In some instances, the resistance reduction techniques include reducing the exposure of S/D dopants to thermal cycles, thereby reducing the diffusion and loss of S/D dopants to surrounding materials. In some such instances, the techniques include delaying the epitaxial deposition of the doped S/D material until near the end of the transistor formation process flow, thereby avoiding the thermal cycles earlier in the process flow (e.g., the thermal cycles associated with replacement gate processes). For example, the techniques may include replacing the S/D regions (e.g., native fin material in the regions to be used for the transistor S/D) with sacrificial S/D material that can then be selectively etched and replaced by highly doped epitaxial S/D material later in the process flow. In some cases, the selective etch may be performed through S/D contact trenches formed in overlying insulator material over the sacrificial S/D, after performing the contact trench etch and before the metal contacts are deposited. The resistance reduction techniques are applicable to a wide range of transistor geometries and configurations, including but not limited to, various field-effect transistors (FETs) such as metal-oxide-semiconductor FETs (MOSFETs) and tunnel-FETs (TFETs), finned configurations (which includes finFET and trigate configurations), planar configurations, nanowire configurations (also referred to as nanoribbon and gate-all-around configurations), p-type doped transistors (e.g., p-MOS), n-type doped transistors (e.g., n-MOS), and devices including both p and n-type doped transistors (e.g., CMOS). Numerous variations and configurations will be apparent in light of this disclosure.

General Overview

As the fin width used for finFET and other non-planar transistors scales, a higher amount of source/drain (S/D) dopant diffuses from the fin into the spacer, reducing carrier concentration and degrading external resistance (Rext). The dopant diffusion can also make the S/D junctions more gradual and reduces the dopant concentration at metal/semiconductor interfaces, causing additional S/D and contact resistance degradation. Techniques have been developed to attempt to address these issues. One such technique is fin necking, where the fin width in the channel is reduced while a relatively thicker fin width is maintained underneath the spacer. Although fin necking can help with S/D resistance problems, fin necking also causes threshold voltage and gate capacitance to increase, which is undesired. Further, fin necking fails to address contact resistance problems.

Thus, and in accordance with one or more embodiments of the present disclosure, techniques are disclosed for resistance reduction under transistor spacers. In some embodiments, the resistance reduction techniques include reducing the exposure of S/D dopants to thermal cycles, thereby reducing the diffusion and loss of S/D dopants to surrounding materials. In some such embodiments, the techniques include delaying the epitaxial deposition of the doped S/D material until near the end of the transistor formation process flow, thereby avoiding the thermal cycles earlier in the process flow (e.g., the thermal cycles associated with replacement gate processes). For example, in some embodiments, the techniques include replacing the S/D regions (e.g., native fin material in the regions to be used for the transistor S/D) with sacrificial S/D material that can then be selectively etched and replaced by highly doped epitaxial S/D material. In some such embodiments, the sacrificial S/D material may be etched out and replaced with the highly doped epitaxial S/D material during S/D metal contact processing, after performing the contact trench etch but before the metal contacts are deposited. The techniques may be used as transistor fin widths are scaled to less than 50, 20, 10, or 8 nm, for example. In addition, the techniques may be used with various channel types and various type metal-oxide-semiconductor (MOS) transistor configurations, such as p-MOS, n-MOS, and/or complementary MOS (CMOS). In embodiments including both p-type and n-type polarities (e.g., in the case of CMOS devices), the techniques may include depositing hardmask in the contact location to mask off structures to be used for one polarity, etching out the sacrificial S/D placeholder material in the structures to be used for the other polarity and depositing the epitaxial S/D of that polarity, and then repeating the process to replace the material in the S/D regions that were originally masked off.

In some embodiments, the techniques may be used for transistor devices including various channel materials, such as silicon (Si), germanium (Ge), and/or one or more III-V materials. In some such embodiments, the sacrificial S/D material may be selected based on the transistor channel material (e.g., to ensure the sacrificial S/D material can be selectively etched relative to the transistor channel material). For example, Ge or SiGe may be used as the sacrificial S/D material for transistors including Si channels, as Ge and SiGe can be selectively etched relative to Si. To provide another example, gallium arsenide (GaAs) may be used as the sacrificial S/D material for transistors including an indium gallium arsenide (InGaAs) channel, as GaAs can be selectively etched relative to InGaAs. To provide yet another example, SiGe with a Ge percentage of approximately 10% or higher Ge content may be used as the sacrificial S/D material for transistors including a SiGe channel (e.g., channel having 20% Ge alloy and sacrificial S/D material having approximately 30% Ge alloy or higher), as such higher Ge content SiGe alloys can be selectively etched relative to lower Ge content SiGe alloys. Note that approximately as used with a percentage amount herein includes plus or minus 1%. Also note that being able to selectively etch a first material relative to a second material includes being able to use a process that removes the first material at least 1.5, 2, 3, 5, 10, 20, 50, or 100 times as fast as the second material, or at least some other relative amount. Accordingly, the selective etch processes may include various etchants, temperatures, pressures, etc. as desired to enable the desired selectivity of the process.

The techniques variously described herein, and the transistor structures formed therefrom, provide numerous benefits. As previously described, in some embodiments, deposition of the doped epitaxial S/D material occurs toward the end of the transistor process flow (e.g., after replacement metal gate (RMG) processing). Such embodiments provide benefits over techniques that deposit the doped epitaxial S/D in the mid-section location of the transistor processing, because the dopant diffusion and loss is significantly reduced. Further, the techniques variously described herein improve more resistance problems without significantly increasing the device capacitance compared to, e.g., fin necking techniques. For example, some benefits over other techniques/structures include increased effective drive current (e.g., by at least 10%), no or minimal gate capacitance penalty (e.g., 1% or less), and minimal overlap capacitance penalty (e.g., 5% or less). In some cases, the use of the techniques variously described herein may be detected by measuring these benefits in other transistor devices (e.g., increase in effective drive current with no or minimal gate capacitance penalty). Numerous other benefits will be apparent in light of the present disclosure.

Upon analysis (e.g., using scanning/transmission electron microscopy (SEM/TEM), composition mapping, secondary ion mass spectrometry (SIMS), time-of-flight SIMS (ToF-SIMS), atom probe imaging, local electrode atom probe (LEAP) techniques, 3D tomography, high resolution physical or chemical analysis, etc.), a structure or device configured in accordance with one or more embodiments will effectively show transistor devices and structures as variously described herein. For example, the techniques/structures described herein may be detected by analyzing the epitaxial S/D in TEM to see if the epitaxy appears to be one continuous film that starts beneath the spacer and extends into the metal contact trenches. Such techniques/structures described herein can be compared to, for example, other techniques/structures that perform highly doped epitaxial S/D deposition prior to deposition of the overlaying insulator layer (e.g., inter-layer dielectric (ILD)). As can be understood, in such other techniques/structures, the epitaxial S/D material would not occupy contact trenches, as the epitaxial S/D regions were formed prior to contact trench etch. But in some embodiments of the present disclosure, the epitaxial S/D material is deposited through the contact trenches (e.g., after the sacrificial S/D material is removed), thereby resulting in some of the material extending into the contact trenches in the insulator material (e.g., in the ILD layer). Numerous configurations and variations will be apparent in light of this disclosure.

Architecture and Methodology

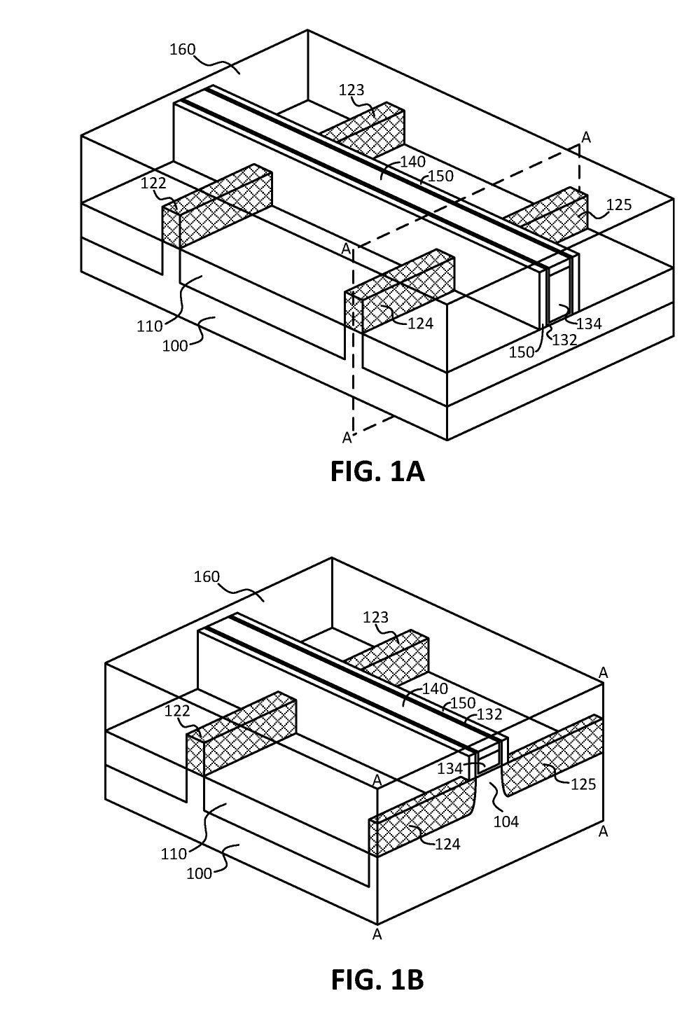

FIG. 1A illustrates an example integrated circuit structure after gate processing and including sacrificial epitaxial S/D material, in accordance with an embodiment of the present disclosure. FIG. 1B illustrates a cross-sectional view of the example integrated circuit structure of FIG. 1A, the cross-section being through the middle of the right fin along plane A, in accordance with an embodiment. As can be seen, in this example embodiment, the integrated circuit structure of FIG. 1A-B includes substrate 100 including two fin structures formed therefrom, shallow trench isolation (STI) material 110 between the fin structures, a gate stack including gate dielectric 132 and gate electrode 134, a hardmask layer 140 formed over the gate stack, side-wall spacers 150 formed on either side of the gate stack, and an insulating material layer 160 formed over the rest of the structure. Note that insulator layer 160 is shown as transparent throughout all figures to allow for the underlying structure to be seen. The example integrated circuit structure includes a left fin having a channel region defined by the gate stack as well as S/D regions 122/123 adjacent to the channel region and a right fin having a channel region 104 defined by the gate stack as well as S/D regions 124/125 adjacent to channel region 104. Note that in FIGS. 1A-B, the channel region of the left fin cannot be seen and the channel region 104 of the right fin can only be seen in the cross-sectional view provided in FIG. 1B. Also note that either of the S/D regions in a pair may be the source while the other is the drain, which may be determined based on the electrical connections made to the regions. For example, in some cases, region 122 may be used as the source and region 123 may be used as the drain, or vice versa, depending on the desired configuration. The components of the example integrated circuit structure will be described in more detail in turn below.

In some embodiments, substrate 100 may be: a bulk substrate including, e.g., Si, SiGe, Ge, and/or at least one III-V material; an X on insulator (XOI) structure where X is Si, SiGe, Ge, and/or at least one III-V material and the insulator material is an oxide material or dielectric material or some other electrically insulating material; or some other suitable multilayer structure where the top layer includes Si, SiGe, Ge, and/or at least one III-V material. In the example embodiment of FIGS. 1A-B, the channel region of the fins are native to substrate 100, as can best be seen in FIG. 1B with channel region 104. As can also be seen, the S/D regions 122/123, 124/125 of each fin have been replaced by a sacrificial material illustrated by a crosshatch pattern. The formation of the fins may have included any suitable techniques. An example process flow to form the fins may include: patterning the substrate 100 with hardmask in areas to be formed into fins, etching the areas that are not masked off to form shallow trench recesses, and depositing shallow trench isolation (STI) material 110 in the recesses. In such an example process flow, additional techniques may be used to form a substrate including fins, such as planarization processes, additional etch processes, or any other suitable process depending on the end use or target application.

In addition and as previously described, in this example embodiment, the S/D regions of the fins were removed and replaced with a sacrificial material. Such a remove and replace process may include any suitable techniques. For example, the S/D regions of the original fins may be defined after dummy gate deposition, the S/D regions of the original fins may then be removed while the S/D regions are exposed (e.g., via an S/D region trench etch in overlaying insulator layer 160), and the sacrificial material of S/D regions 122/123 and 124/125 may then be deposited to form the S/D regions illustrated in FIGS. 1A-B. After the S/D regions have been removed and replaced, additional insulator material may then be deposited over the structure (followed by an optional planarization process), to cover and protect the S/D regions during replacement gate processing or other subsequent processing. Note that the shape of the fins in the example embodiment of FIGS. 1A-B is used for ease of illustration and the present disclosure is not intended to be limited to just the shapes shown. The sacrificial material of the S/D regions will be described in more detail below.

In some embodiments, the fins may be formed to have varying widths and heights. For example, in an aspect ratio trapping (ART) integration scheme, the fins may be formed to have particular height to width ratios such that when they are later removed or recessed, the resulting trenches formed allow for defects in the replacement material deposited to terminate on a side surface as the material grows vertically, such as non-crystalline/dielectric sidewalls, where the sidewalls are sufficiently high relative to the size of the growth area so as to trap most, if not all, of the defects. In such an example case, the height to width ratio (h/w) of the fins may be greater than 1, such as greater than 1.5, 2, or 3, or any other suitable minimum ratio, for example. Note that although only two fins are shown on the example integrated circuit of FIGS. 1A-B for illustrative purposes, any number of fins may be formed, such as one, five, ten, hundreds, thousands, millions, etc., depending on the end use or target application. Also note that the sacrificial material of S/D regions 122/123 and 124/125 may overgrow the replaced original fin portion in multiple dimensions, such that the sacrificial epitaxial material will be wider than the underlying fin or sub-fin region (the region sandwiched between STI regions 110), for example. Accordingly, although the sacrificial material of S/D regions 122/123 and 124/125 is shown as having the same width as the underlying fin portion for ease of illustration, the present disclosure is not intended to be so limited. For example, in many practical applications, the epitaxial material will not be so perfectly formed as shown in FIGS. 1A-B, as the epitaxial material will grow both vertically and laterally above the sub-fin region.

In this example embodiment, the STI regions (or isolation regions) 110 may be formed between sub-fin portions as shown to, for example, prevent or minimize electric current leakage between the adjacent semiconductor devices formed from the fins. STI material 120 may include any suitable insulating material, such as one or more dielectric, oxide (e.g., silicon dioxide), or nitride (e.g., silicon nitride) materials. In some embodiments, the STI material 110 may be selected based on the material of substrate 100 (which may also be the material of the sub-fin portions native to the substrate). For example, in the case of a Si substrate 100, STI material 110 may selected to be silicon dioxide or silicon nitride. In addition, in this example embodiment, insulator layer 160 may be formed using any suitable techniques and any suitable material, such as blanket depositing a low-k dielectric material on the underlying structure (followed by an optional planarization process). Such insulator materials include, for example, oxides such as silicon dioxide and carbon doped oxide, nitrides such as silicon nitride, organic polymers such as perfluorocyclobutane or polytetrafluoroethylene, fluorosilicate glass, and organosilicates such as silsesquioxane or siloxane or organosilicate glass. In some embodiments, insulator layer 160 may include pores or other voids to further reduce the dielectric constant of the layer.

In this example embodiment, the integrated circuit structure includes a gate stack including gate dielectric 132 formed to define the fin channel regions. The gate stack also includes a gate electrode 134 formed on the gate dielectric. As can also be seen in this example embodiment, the integrated circuit structure includes hardmask 140 over gate electrode 134 and side wall spacers 150 on either side of the gate stack. The gate dielectric and gate electrode may be formed using any suitable techniques. For example, in some embodiments, the formation of the gate stack may include dummy gate oxide deposition, dummy gate electrode (e.g., poly-Si) deposition, and patterning hardmask deposition. Additional processing may include patterning the dummy gates and depositing/etching spacer material. Following such processes, the method may continue with insulator deposition, planarization, and then dummy gate electrode and gate oxide removal to expose the channel region of the transistors, such as is done for a replacement metal gate (RMG) process. Following opening the channel region, the dummy gate oxide and electrode may be replaced with, for example, a hi-k dielectric and a replacement metal gate, respectively. Other embodiments may include a standard gate stack formed by any suitable process. In this example embodiment, the gate shown is an RMG, where a dummy gate was used to facilitate formation of the replacement gate. Accordingly, as previously described, in some embodiments, the resistance reduction techniques include processing the S/D regions after the replacement gate processing to reduce exposure of the final doped S/D material to thermal cycles that occur during gate processing. Such techniques reduce the diffusion and loss of S/D dopants into surrounding materials as a result of the thermal processes that occur during gate processing, as will be apparent in light of the present disclosure.

In some embodiments, the gate dielectric 132 may be, for example, any suitable oxide material (such as silicon dioxide) or a high-k gate dielectric material. Examples of high-k gate dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used. In general, the thickness of the gate dielectric 132 should be sufficient to electrically isolate the gate electrode from the source and drain contacts. In some embodiments, the gate dielectric may have a thickness of 0.5 to 3 nm, or any other suitable thickness, depending on the end use or target application. In some embodiments, the gate electrode 134 may include a wide range of materials, such as polysilicon, silicon nitride, silicon carbide, or various suitable metals or metal alloys, such as aluminum (Al), tungsten (W), titanium (Ti), tantalum (Ta), copper (Cu), titanium nitride (TiN), or tantalum nitride (TaN), for example. In embodiments where gate electrode 134 includes metal, the metal gate electrode can be variable workfunction (e.g., to assist with tuning to the proper threshold voltage of the device).

In this example embodiment, hardmask layer 140 is present to provide benefits during processing, such as protecting the gate electrode 134 from processes performed after the deposition of the gate electrode material (e.g., ion implantation processes). Hardmask layer 140 may be formed using any suitable techniques and may include any suitable materials, such as silicon dioxide or silicon nitride, for example. Note that in some embodiments, hardmask layer 140 may not be present or it may be at least partially removed during subsequent processing to allow for making contact with the gate electrode 134, for example. In this example embodiment, side wall spacers 150 (or simply, spacers) are formed adjacent to the gate stack and may have been formed to assist with the replacement gate process, for example. Spacers 150 may be formed using any suitable techniques and may include any suitable materials, such as silicon oxide or silicon nitride, for example. The width of spacers 150 may be selected as desired, depending on the end use or target application. As can be seen in FIG. 1B, looking specifically at the right fin, the S/D regions 124/125 extend under spacers 150, as the gate stack (including gate dielectric 132 and gate electrode 134) defines channel region 104. The techniques as variously described herein can be used to help reduce the resistance that occurs in the S/D material under spacers 150, as well as provide other benefits as will be apparent in light of the present disclosure.

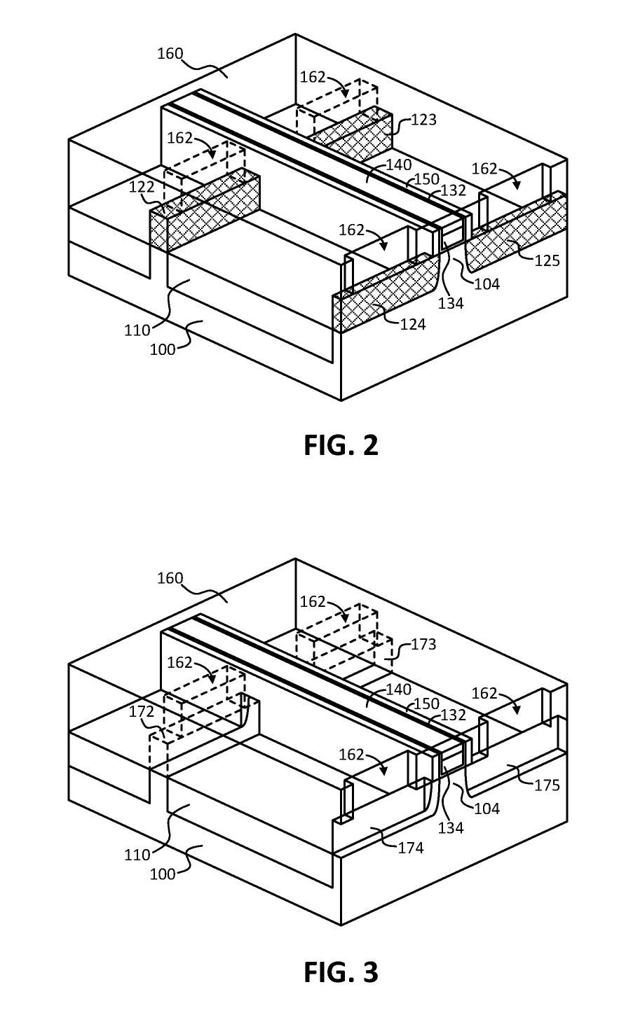

FIG. 2 illustrates the example integrated circuit structure of FIG. 1B, after forming S/D contact trenches 162 in insulator layer 160, in accordance with an embodiment of the present disclosure. As can be seen in FIG. 2, contact trenches 162 were formed above the S/D regions 122/123 and 124/125 to allow for later deposition of metals to make electrical contact with the regions. Contact trenches 162 may be formed using any suitable techniques, such as any suitable lithography, hardmask, and etch processes, for example. Note that the shape of the contact trenches 162 are used for ease of illustration and the present disclosure is not intended to be limited to just the shape shown. Such contact trenches 162 are typically formed after gate and S/D processing are complete to make contact to the S/D regions. For example, in such a standard process, the sacrificial S/D material 122/123 and 124/125 would be used as the final device epitaxial S/D and the standard process would continue with depositing the contact metal in contract trenches 162. As can be understood, in such a standard process, the S/D material would not extend into the contact trenches 162. However, in this example embodiment, as will be apparent, additional S/D processing will occur through contact trenches 162 to remove the sacrificial S/D material and deposit the final doped material in the S/D regions, resulting in the final S/D material extending at least partially into the contact trenches (or conversely, resulting in the contact metal extending at least partially into the S/D region).

FIG. 3 illustrates the example integrated circuit structure of FIG. 2, after the sacrificial S/D material 122/123 and 124/125 has been removed to form S/D trenches 172/173 and 174/175, in accordance with an embodiment of the present disclosure. In this example embodiment, removal of the sacrificial S/D material 122/123 and 124/125 is performed through contact trenches 162 using a wet/chemical etch. However, any suitable removal processes may be used based on, for example, the stage in the process flow that the sacrificial S/D material is being removed. As the transistor channel material may include Si, SiGe, Ge, and/or one or more III-V materials in this example embodiment, the sacrificial S/D material 122/123 and 124/125 may be selected based on the transistor channel material to, for example, ensure the sacrificial S/D material can be selectively etched relative to the transistor channel material. For example, Ge or SiGe may be used as the sacrificial S/D material for Si-based channels, as Ge and SiGe can be selectively etched relative to Si. To provide another example, gallium arsenide (GaAs) may be used as the sacrificial S/D material for transistors including an indium gallium arsenide (InGaAs) channel, as GaAs can be selectively etched relative to InGaAs. To provide yet another example, a germanium tin (GeSn) alloy may be used as the sacrificial S/D material for transistors including a Ge or SiGe with greater than 80% Ge content channel, as GeSn can be selectively etched relative to Ge or Si₁₋ₓGeₓ where x>0.8. To provide yet another example, SiGe channels with less than 80% Ge content may use a sacrificial S/D material of SiGe having a Ge percentage of at least approximately 10% higher Ge content than the Ge content in the channel SiGe material (e.g., SiGe channel having 20% Ge content and sacrificial S/D SiGe material having approximately 30% Ge content or higher), as such higher Ge content SiGe alloys can be selectively etched relative to lower Ge content SiGe alloys. Further note that in some embodiments, the sacrificial S/D material may be doped to, for example, assist with the selective etching of the material relative to the channel material and surrounding dielectric material. Therefore, in some embodiments, the sacrificial S/D material 122/123 and 124/125 may be selected based on the channel material (which may or may not be native to substrate 100). Note that approximately as used with a percentage amount herein includes plus or minus 1%. Also note that being able to selectively etch a first material relative to a second material includes being able to use a process that removes the first material at least 1.5, 2, 3, 5, 10, 20, 50, or 100 times as fast as the second material, or at least some other relative amount. Accordingly, the selective etch processes may include various etchants, temperatures, pressures, etc. as desired to enable the desired selectivity of the process.

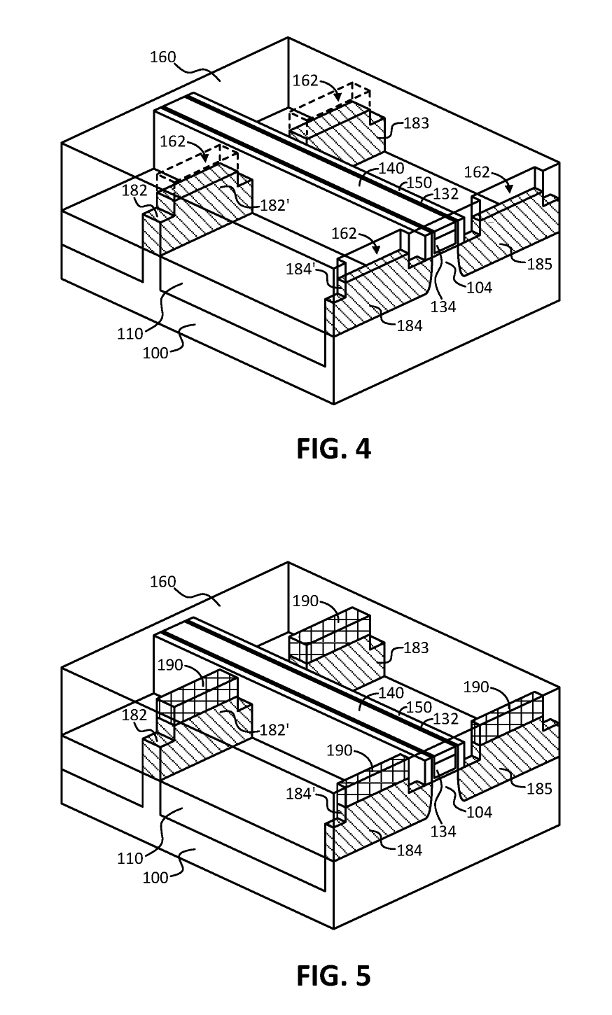

FIG. 4 illustrates the example integrated circuit structure of FIG. 3, after depositing replacement S/D material 182/183 and 184/185 in S/D trenches 172/173 and 174/175, in accordance with an embodiment of the present disclosure. The deposition may be performed using any suitable techniques and in this example embodiment, is performed through contact trenches 162 to at least substantially fill S/D trenches 172/173 and 174/175. Replacement S/D material, in this example embodiment, is a doped epitaxial material to be used for the final S/D regions of transistor devices formed therefrom. For example, the S/D material may include Si, SiGe, Ge, and/or at least one III-V material, and that material may be doped depending on the end use or target application (e.g., n-type doped for n-MOS application, p-type doped for p-MOS application, etc.). As can be seen in FIG. 4, because the replacement S/D material is deposited through contact trenches 162, a portion of the material extends into the trenches. This is illustrated for S/D region 182 as 182′ and S/D region 184 as 184′, although the overflow of the replacement S/D material into the contact trenches 162 also occurs for S/D regions 183 and 185. As previously described, depositing the final S/D material 182/183 and 184/185 after gate processing (e.g., to form gate dielectric 132 and gate electrode 134) provides the benefit of reducing the exposure of the S/D dopants to thermal cycles used during replacement gate processing. As was also previously described, structures using the resistance reduction techniques variously described herein may be detected by looking at the epitaxial S/D region and determining if the S/D material starts beneath the spacer and extends into the S/D contact trenches, as is shown in FIG. 4. This can be contrasted with a standard structure that does not employ the resistance reduction techniques variously described herein, where the standard epitaxial S/D processing occurs prior to S/D contact trench etch. Such a structure would be illustrated in FIG. 2, if the sacrificial S/D material 122/123 and 124/125 were instead used as the final doped S/D material. In such a standard structure, the S/D material does not extend into the contact trenches 162, as the trenches are made after the final epitaxial S/D material has been deposited.

FIG. 5 illustrates the example integrated circuit structure of FIG. 4, after depositing metal S/D contacts 190 in contact trenches 162, in accordance with an embodiment of the present disclosure. The deposition of the metal S/D contacts 190 may be performed using any suitable techniques. In some embodiments, contacts 190 may include aluminum or tungsten, although any suitable conductive metal or alloy can be used, such as silver, nickel-platinum, or nickel-aluminum, for example. In some embodiments, metallization of the S/D contacts 190 may be carried, for example, using a germanidation process (generally, deposition of contact metal and subsequent annealing). The Ge-rich layers can allow for metal-germanide formation (e.g., nickel-germanium), which may be desired in some embodiments. Although the resistance reduction techniques variously described herein are in the context of removing the sacrificial S/D material and replacing with final doped S/D device material through contact trenches, the present disclosure need not be so limited. In other embodiments, the removal of the sacrificial S/D material and replacement with the final S/D device material may be performed at another location of the transistor formation process flow after the replacement gate processing has been performed (e.g., to prevent exposure of the final S/D device material to the thermal processing that occurs during the replacement gate processing). Numerous variations on the techniques described herein will be apparent in light of the present disclosure.

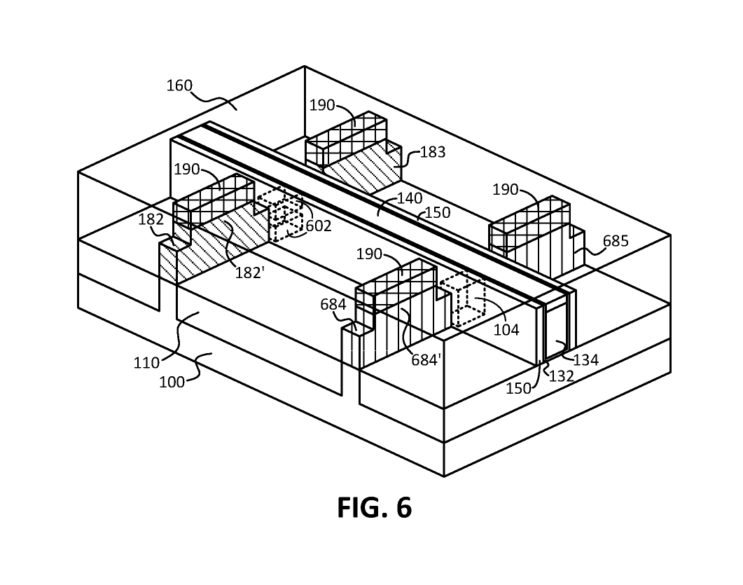

FIG. 6 illustrates variations that can be made to the example integrated circuit structure of FIG. 5, in accordance with some embodiments of the present disclosure. Note that FIG. 6 is shown without the cross-sectional view taken along plane A in FIG. 1A, for ease of illustration. As can be seen in FIG. 6, the S/D regions 184/185 have been replaced by S/D regions 684/685 of a different material. Such a variation may be achieved by masking off the S/D regions of the integrated circuit structure in FIG. 1A-B over S/D regions 124/125, performing the techniques to replace the sacrificial S/D material with the doped S/D material 182/183 shown in FIGS. 2-5, and repeating the process to remove the sacrificial S/D material 124/125 with S/D material 684/685 (e.g., including removing the mask over the S/D regions to be removed/replaced and masking off the other S/D regions, such as regions 182/183). As can be understood, the masking and remove/replace processes can be repeated as many times as desired to create sets of as many different S/D regions as desired. As can also be understood, efficiency can be gained by replacing all native S/D regions with a sacrificial material in those S/D regions in the first instance before performing the masking and remove/replace processes as desired, based on the end use or target application. Note that portions of S/D regions 684/685 extend into their respective contact trenches, which is indicated as 684′ for S/D region 684, for example.

FIG. 6 also illustrates that the resulting transistor structures can have any desired configuration. For example, channel region 104, as originally shown in FIG. 1B, is illustrated as a finned configuration in FIG. 6, as the original native fin portion was maintained in this example embodiment. However, the channel region of the left fin (including S/D regions 182/183) was changed to a nanowire channel 602 configuration. A nanowire transistor (sometimes referred to as a gate-all-around or nanoribbon transistor) is configured similarly to a fin-based transistor, but instead of a finned channel region where the gate is on three sides (and thus, there are three effective gates), one or more nanowires are used and the gate material generally surrounds each nanowire on all sides. Depending on the particular design, some nanowire transistors have, for example, four effective gates. In some embodiments, the lowermost nanowire may be similar to a finned channel region, in that it only has three effective gates due to the gate only being on three sides. As can be seen in the example structure of FIG. 6, channel region 602 has two nanowires, although other embodiments can have any number of nanowires. The nanowires 602 may have been formed while the channel regions were exposed during a replacement gate process (e.g., an RMG process), after the dummy gate is removed, for example. In some embodiments, the channel regions may be native to the substrate (and thus include the same material as the substrate, with or without doping), or replacement channel regions that include the same material as the substrate or different replacement material, or some combination thereof.

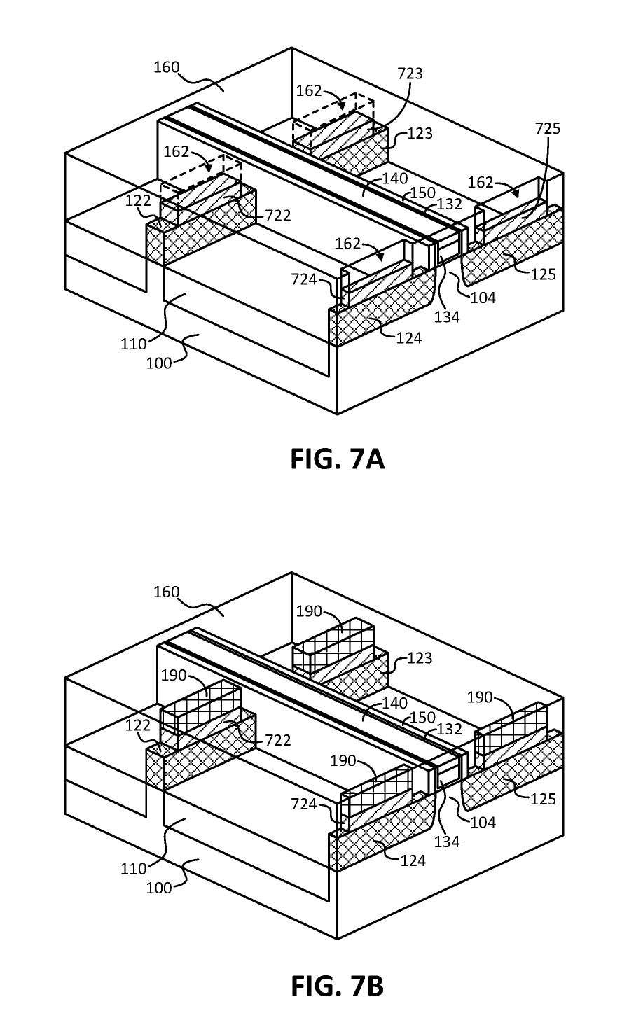

FIGS. 7A-B illustrate depositing additional epitaxial material in the S/D contact trenches formed in FIG. 2, in accordance with an embodiment of the present disclosure. As can be seen in FIG. 7A, the example structure continues from the example structure illustrated in FIG. 2, where contact trenches 162 were formed above the epitaxial S/D regions 122/123 and 124/125. In this example embodiment, the process flow does not include removing epitaxial S/D regions 122/123 and 124/125 through contact trenches 162. Accordingly, epitaxial S/D regions 122/123 and 124/125 from FIG. 2 are not sacrificial in this embodiment, but instead are to be used as a part of the final S/D material (and thus including proper doping, etc.). In other words, in this example embodiment, the epitaxial S/D processing is not delayed until the end of the transistor process flow (e.g., compared to the example embodiment shown in FIGS. 3-6, where the final epitaxial S/D processing was delayed until the end of the transistor process flow). Instead, in the example embodiment of FIGS. 7A-B, additional highly doped epitaxial material 722, 723, 724, and 725 is deposited in contact trenches 162 and on epitaxial S/D regions 122,123, 124, and 125, respectively, toward the end of the process flow (e.g., after gate processing has occurred but before contact metals are deposited). Such an embodiment can realize gains in contact resistance as the dopant at the additional epitaxial material 722, 723, 724, 725 and metal contact 190 interface avoids most thermal cycles. However, such an embodiment may not realize gains in resistance under the spacer, as the dopant underneath the spacer does not avoid most of the thermal cycles. Note that, all previous discussion of relevant features (e.g., gate dielectric 132, gate 134, contacts 190, etc.) is equally applicable to the structures of FIGS. 7A-B. Also note that, in some cases, the additional epitaxial regions 722, 723, 724, and 725 formed in the S/D contact trenches may include the same material as the underlying epitaxial S/D material in 122, 123, 124, and 125, respectively, or the additional epitaxial material may be different, in some cases.

Various different transistor configurations and geometries can benefit from the techniques and structures variously described herein. For example, the doping of the S/D and channel may be selected based on the desired transistor configuration. For example, for a p-type MOS (p-MOS) transistor, the S/D regions may be p-type doped and the channel may be n-type doped. In another example, for an n-type MOS (n-MOS) transistor, the S/D regions may be n-type doped and the channel may be p-type doped. In some embodiments, both p-MOS and n-MOS devices may be included to form a CMOS device, for example. In another example, for a tunnel field-effect transistor (TFET), the source may be p-type or n-type doped, the drain may be doped with an opposite polarity from the source (e.g., n-type doped when the source is p-type doped), and the channel may be undoped or intrinsic. In some embodiments, both p-TFET and n-TFET device may be included to form a complementary TFET (CTFET) device. Example transistor geometries that can benefit from the techniques described herein include, but are not limited to, field-effect transistors (FETs), metal-oxide-semiconductor FETs (MOSFETs), tunnel-FETs (TFETs), planar configurations, finned configurations (e.g., fin-FET, tri-gate), and nanowire (or nanoribbon or gate-all-around) configurations. Numerous variations and configurations will be apparent in light of the present disclosure.

Table 1 below illustrates simulation results for multiple measured items for an n-MOS transistor including A) a standard structure, B) a necked fin structure, and C) epitaxial S/D replaced through contact trenches or at the time of contact processing (e.g., as variously described herein). As can be understood, higher percentages are desired for effective drive current (Ieff) and lower percentages are desired for gate capacitance (Cgate) and overlap capacitance (Covw).

TABLE 1

| Structure | leff@0.6 V | leff@1.1 V | Cgate@1.1 V | Covw@1.1 V |
|---|---|---|---|---|
| A) | 0% | 0% | 0% | 0% |
| Standard | | | | |
| B) Necked | 3% | 12% | 3% | 9% |
| Fin | | | | |
| C) Epi | 11% | 14% | 0% | 5% |
| S/D | | | | |
| Replaced | | | | |
| at Contact | | | | |

As can be seen in Table 1, transistors including C) epitaxial S/D replacement through contact trenches as variously described herein provides greater than 10% effective drive current (Ieff) gain over A) a standard structure at both 0.6V and 1.1V, has no gate capacitance (Cgate), and only 5% overlap capacitance (Covw) penalty. This can be compared to B) a necked fin approach, which may be used to address the issue of resistance under a transistor spacer, and as can be seen in Table 1, structure C) is favorable in all four categories (Ieff@0.6V, Ieff@1.1V, Cgate@1.1V, and Covw@1.1V). Numerous other benefits will be apparent in light of the present disclosure.

Example System

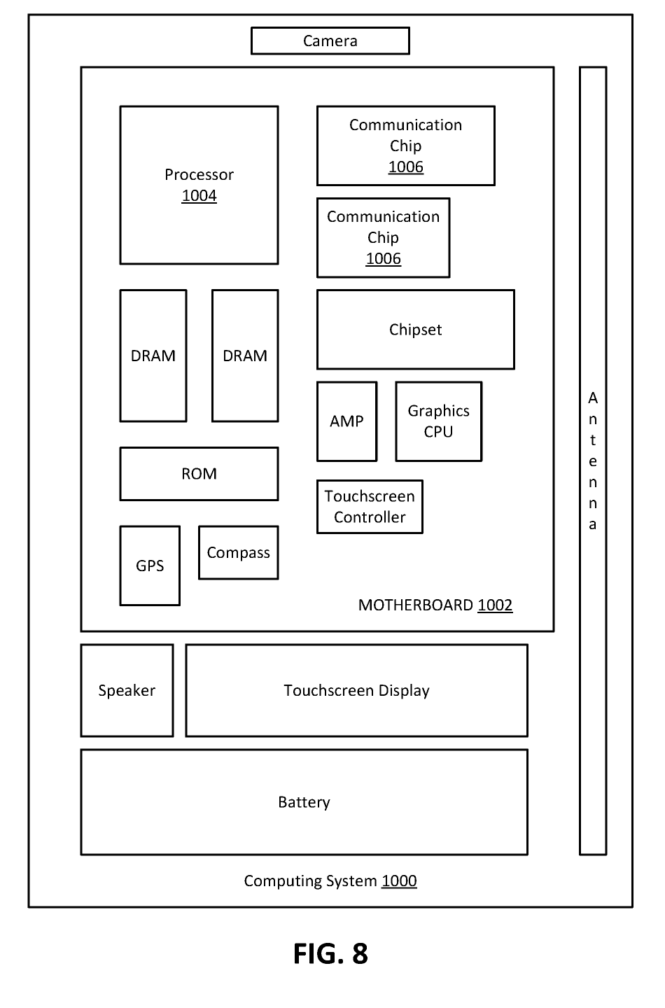

FIG. 8 illustrates an example computing system 1000 implemented with integrated circuit structures or devices formed using the techniques disclosed herein, in accordance with one or more embodiments of the present disclosure. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing device 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

### Further Example Embodiments

The following examples pertain to further embodiments, from which numerous permutations and configurations will be apparent.

Example 1 is a transistor including: a substrate; a gate stack including a gate dielectric and gate electrode, the gate stack defining a channel above and/or native to the substrate; spacers on either side of the gate stack; source and drain (S/D) regions adjacent the channel; an insulator layer located above the substrate; and metal contacts electrically connected to the S/D regions, the metal contacts located in contact trenches in the insulator layer; wherein the S/D material is located beneath at least a portion of the spacers and extends into at least a portion of the contact trenches.

Example 2 includes the subject matter of Example 1, wherein the channel is native to the substrate.

Example 3 includes the subject matter of any of Examples 1-2, wherein the channel includes at least one of silicon and germanium.

Example 4 includes the subject matter of any of Examples 1-3, wherein the channel includes at least one III-V material.

Example 5 includes the subject matter of any of Examples 1-4, wherein the gate dielectric is at least one of silicon dioxide and a high-k dielectric material.

Example 6 includes the subject matter of any of Examples 1-5, wherein the S/D material is doped epitaxial material.

Example 7 includes the subject matter of any of Examples 1-6, wherein the transistor has a finned channel configuration.

Example 8 includes the subject matter of any of Examples 1-6, wherein the transistor has a nanowire or nanoribbon channel configuration.

Example 9 includes the subject matter of any of Examples 1-8, wherein the transistor is a p-type metal-oxide-semiconductor (p-MOS) transistor.

Example 10 includes the subject matter of any of Examples 1-8, wherein the transistor is an n-type metal-oxide-semiconductor (n-MOS) transistor.

Example 11 includes the subject matter of any of Examples 1-8, wherein the transistor is a tunnel field-effect transistor (TFET).

Example 12 is a complementary metal-oxide-semiconductor (CMOS) or complementary tunnel field-effect transistor (CTFET) device including the subject matter of any of Examples 1-11.

Example 13 is an integrated circuit including two transistors of any of Examples 1-11, wherein the S/D material of the first transistor is different than the S/D material of the second transistor.

Example 14 is a computing system including the subject matter of any of Examples 1-13.

Example 15 is an integrated circuit including: a substrate; an insulator layer located above the substrate; at least two transistors on the substrate, each transistor including: a gate defining a channel above and/or native to the substrate; spacers on either side of the gate; source and drain (S/D) regions adjacent the channel region; and metal contacts electrically connected to the S/D regions of each transistor, the metal contacts located in contact trenches in the insulator layer; wherein the S/D material of each transistor is located beneath at least a portion of the spacers and extends into at least a portion of the contact trenches.

Example 16 includes the subject matter of Example 15, wherein at least one transistor channel is native to the substrate.

Example 17 includes the subject matter of any of Examples 15-16, wherein each transistor channel includes at least one of silicon, germanium, and a III-V material.

Example 18 includes the subject matter of any of Examples 15-17, wherein the S/D material of each transistor is doped epitaxial material.

Example 19 includes the subject matter of any of Examples 15-18, wherein at least one transistor has a finned channel configuration.

Example 20 includes the subject matter of any of Examples 15-19, wherein at least one transistor has a nanowire or nanoribbon channel configuration.

Example 21 includes the subject matter of any of Examples 15-20, wherein at least one transistor is a p-type metal-oxide-semiconductor (p-MOS) transistor.

Example 22 includes the subject matter of any of Examples 15-21, wherein at least one transistor is an n-type metal-oxide-semiconductor (n-MOS) transistor.

Example 23 includes the subject matter of any of Examples 15-22, wherein at least one transistor is a p-type metal-oxide-semiconductor (p-MOS) transistor and at least one transistor is an n-type metal-oxide-semiconductor (n-MOS) transistor.

Example 24 includes the subject matter of any of Examples 15-22, wherein at least one transistor is a tunnel field-effect transistor (TFET).

Example 25 includes the subject matter of any of Examples 15-24, wherein each transistor is at least one of a field-effect transistor (FET), metal-oxide-semiconductor FET (MOSFET), tunnel-FET (TFET), finned configuration transistor, finFET configuration transistor, trigate configuration transistor, nanowire configuration transistor, nanoribbon configuration transistor, and gate-all-around configuration transistor.

Example 26 is a computing system including the subject matter of any of Examples 15-25.

Example 27 is a method of forming a transistor, the method including: providing a substrate; forming a fin from the substrate; forming a first gate stack on the fins, the gate stack including spacers on two sides of the first gate stack, wherein the first gate stack defines a channel region and source and drain (S/D) regions in the fin; removing at least a portion of the S/D regions of the fin and depositing sacrificial material at the S/D regions; replacing the first gate stack with a second gate stack; etching contact trenches in an insulator layer over the S/D regions of the fin; and removing the sacrificial material at the S/D regions through the contact trenches and depositing doped S/D material at the S/D regions.

Example 28 includes the subject matter of Example 27, wherein removing the sacrificial material at the S/D regions is performed via a chemical etch.

Example 29 includes the subject matter of Example 28, wherein the chemical etch selectively removes the sacrificial material relative to the channel region material.

Example 30 includes the subject matter of Example 29, wherein selectively removes includes removing the sacrificial material at least ten times faster than the channel region material.

Example 31 includes the subject matter of any of Examples 27-29, further including: masking the S/D region of the fin after the doped S/D material has been deposited at the S/D regions; etching contact trenches in the insulator layer over the S/D regions of the other fin; and removing the sacrificial material at the S/D regions of the other fin through the contact trenches and depositing doped S/D material at the S/D regions of the other fin.

Example 32 includes the subject matter of Example 31, wherein the doped S/D material deposited at the S/D regions of the fin is different than the doped S/D material deposited at the S/D regions of the other fin.

Example 33 includes the subject matter of any of Examples 27-32, wherein replacing the first gate stack with a second gate stack is performed using a replacement metal gate (RMG) process.

Example 34 includes the subject matter of any of Examples 27-33, wherein the transistor has a finned channel configuration.

Example 35 includes the subject matter of any of Examples 27-33, wherein the transistor has a nanowire or nanoribbon channel configuration.

Example 36 includes the subject matter of any of Examples 27-35, wherein the transistor is a p-type metal-oxide-semiconductor (p-MOS) transistor.

Example 37 includes the subject matter of any of Examples 27-35, wherein the transistor is an n-type metal-oxide-semiconductor (n-MOS) transistor.

Example 38 includes the subject matter of any of Examples 27-35, wherein the transistor is a tunnel field-effect transistor (TFET).

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

1. An integrated circuit structure including a transistor, the integrated circuit structure comprising:
a gate stack at least over a semiconductor region, the gate stack including a gate dielectric and gate electrode, the gate dielectric between the semiconductor region and the gate electrode;
a gate spacer adjacent the gate stack;
a source region or drain region adjacent the semiconductor region;
an insulator layer above the source region or drain region; and
a contact comprising metal and electrically connected to the source region or drain region, the contact located in a contact trench in the insulator layer;
wherein semiconductor material of the source region or drain region is located beneath at least a portion of the gate spacer and extends into at least a portion of the contact trench.

2. The integrated circuit structure of claim 1, wherein the semiconductor region is native to an underlying substrate.

3. The integrated circuit structure of claim 1, wherein the semiconductor region includes at least one of silicon and germanium.

4. The integrated circuit structure of claim 1, wherein the semiconductor region includes at least one III-V material.

5. The integrated circuit structure of claim 1, wherein the gate dielectric is at least one of silicon dioxide and a high-k dielectric material.

6. The integrated circuit structure of claim 1, wherein the semiconductor material of the source region or drain region is doped epitaxial material.

7. The integrated circuit structure of claim 1, wherein the semiconductor region has a finned channel configuration.

8. The integrated circuit structure of claim 1, wherein the semiconductor region has a nanowire or nanoribbon channel configuration.

9. (canceled)

10. (canceled)

11. (canceled)

12. (canceled)

13. The integrated circuit structure of claim 1, wherein the transistor is a first transistor, the integrated circuit structure further comprising a second transistor, wherein the semiconductor material of the source region or drain region of the first transistor is compositionally different than semiconductor material of a source region or drain region the second transistor.

14. A computing system comprising the integrated circuit structure of claim 1.

15. An integrated circuit comprising:
an insulator layer;
first and second transistors, each including:
a gate stack at least over a semiconductor region;
a gate spacer adjacent the gate stack;
a source region or drain region adjacent the semiconductor region; and
a first contact comprising metal and electrically connected to the source region or drain region of the first transistor, the first contact located in a first contact trench in the insulator layer;
a second contact comprising metal and electrically connected to the source region or drain region of the second transistor, the second contact located in a second contact trench in the insulator layer;
wherein a first semiconductor material of the source region or drain region of the first transistor extends into at least a portion of the first contact trench; and
wherein a second semiconductor material of the source region or drain region of the second transistor extends into at least a portion of the second contact trench.

16. The integrated circuit of claim 15, wherein at least one semiconductor region is native to the substrate.

17. The integrated circuit of claim 15, wherein the semiconductor region of each of the first and second transistors includes at least one of silicon, germanium, and a III-V material.

18. The integrated circuit of claim 15, wherein at least one of the first and second transistors is a p-type metal-oxide-semiconductor (p-MOS) transistor.

19. The integrated circuit of claim 15, wherein at least one of the first and second transistors is an n-type metal-oxide-semiconductor (n-MOS) transistor.

20. The integrated circuit of any of claim 15, wherein each of the first and second transistor is at least one of a field-effect transistor (FET), metal-oxide-semiconductor FET (MOSFET), tunnel-FET (TFET), finned configuration transistor, finFET configuration transistor, trigate configuration transistor, nanowire configuration transistor, nanoribbon configuration transistor, and gate-all-around configuration transistor.

21. A method of forming a transistor, the method comprising:
forming a fin from a substrate;
forming a gate stack on the fin;
removing at least a portion of the fin adjacent the gate stack to define a recess, and depositing sacrificial material into the recess thereby forming a sacrificial source region or drain region;
depositing an insulator layer over the sacrificial source region or drain region;
etching a contact trench in the insulator layer over the source region or drain region; and
removing at least some of the sacrificial material in the source region or drain region through the contact trench, and depositing doped semiconductor material into the source region or drain region through the contact trench.

22. The method of claim 21, wherein the gate stack is a dummy gate stack, the method further comprising:
replacing the dummy gate stack with a final gate stack.

23. The method of claim 21, wherein the fin is a first fin and the contact trench is a first contact trench, the method further comprising:
prior to etching of the first contact trench and removing of the sacrificial material, masking a source region or drain region of a second fin;
masking the source region or drain region of the first fin after the doped semiconductor material has been deposited;
etching a second contact trench in the insulator layer over the source region or drain region of the second fin; and
removing sacrificial material from the source region or drain region of the second fin through the second contact trench, and depositing doped semiconductor material in the source region or drain region of the second fin through the second contact trench.

24. The method of claim 23, wherein the doped semiconductor material deposited in the source region or drain region of the first fin is compositionally different than the doped semiconductor material deposited in the source region or drain region of the second fin.

25. (canceled)
